(19) United States
(12) Patent Application Publication
(10) Pub. No.: US 2025/0364221 A1
(43) Pub. Date: Nov. 27, 2025

(54) PLASMA PROCESSING METHOD, PRECOAT FORMING METHOD, AND PLASMA PROCESSING APPARATUS

(71) Applicant: Tokyo Electron Limited, Tokyo (JP)

(72) Inventors: Yusuke SHIMIZU, Miyagi (JP); Keito EBIHARA, Miyagi (JP)

(73) Assignee: Tokyo Electron Limited, Tokyo (JP)

(21) Appl. No.: 19/289,276

(22) Filed: Aug. 4, 2025

Related U.S. Application Data
(63) Continuation of application No. PCT/JP2024/004790, filed on Feb. 13, 2024.

(30) Foreign Application Priority Data
Feb. 13, 2023 (JP) 2023-020278

(51) Int. Cl. H01J 37/32

(52) U.S. Cl. CPC H01J 37/32449; H01J 37/32082; H01J 2237/332

(57) ABSTRACT

In one exemplary embodiment, a plasma processing method is provided. This method includes (a) forming a precoat on a constituent member in a chamber the precoat including a carbon-containing film; (b) providing a first substrate on a substrate support in the chamber; and (c) performing plasma processing on the first substrate. The (a) includes (a1) supplying a first processing gas including a first gas in the chamber, the first processing gas containing carbon and hydrogen, (a2) supplying a source RF signal to form plasma from the first processing gas, and (a3) supplying a bias signal of 90 eV or more to the constituent member in the chamber.

### CROSS-REFERENCE TO RELATED APPLICATIONS

The present application is a bypass continuation of international PCT Application No. PCT/JP2024/004790 filed on Feb. 13, 2024, which claims priority under 35 U.S.C. § 119 to Japanese Patent Application No. 2023-020278 filed on Feb. 13, 2023, the entire contents of each are incorporated herein by reference.

### BACKGROUND

### Field

An exemplary embodiment of the present disclosure relates to a plasma processing method, a precoat forming method, and a plasma processing apparatus.

### Description of Related Art

JP2008-505490A discloses a technique of precoating a plasma processing chamber.

### SUMMARY

In one exemplary embodiment of the present disclosure, there is provided a plasma processing method, including: (a) forming a precoat on a constituent member in a chamber, the precoat including a carbon-containing film; (b) providing a first substrate on a substrate support in the chamber; and (c) performing plasma processing on the first substrate, wherein the (a) includes (a1) supplying a first processing gas including a first gas in the chamber, the first gas containing carbon and hydrogen, (a2) supplying a source RF signal to form plasma from the first processing gas, and (a3) supplying a bias signal of 90 eV or more to the constituent member in the chamber.

### BRIEF DESCRIPTION OF DRAWINGS

FIG. 1 is a diagram for describing a configuration example of a plasma processing apparatus.

FIG. 2 is a diagram for describing a configuration example of a capacitively coupled plasma processing apparatus.

FIG. 3 is a flowchart illustrating an example of the present processing method.

FIG. 4 is a flowchart illustrating a first example of step ST1.

FIG. 5 is a diagram illustrating an example of a relationship between energy of the ions incident on a constituent member CP and a Raman spectrum.

FIG. 6 is a diagram illustrating an example of a cross-sectional structure of the constituent member CP at an end of step ST13.

FIG. 7 is a flowchart illustrating a second example of step ST1.

FIG. 8 is a flowchart illustrating a third example of step ST1.

FIG. 9 is a flowchart illustrating another example of the present processing method.

FIG. 10A is a diagram illustrating an example of a cross-sectional structure of the constituent member CP at an end of step ST1.

FIG. 10B is a diagram illustrating an example of a cross-sectional structure of the constituent member CP at the end of step ST1.

FIG. 11 is a flowchart illustrating a first example of step STA.

FIG. 12 is a flowchart illustrating a second example of step STA.

FIG. 13 is a flowchart illustrating another example of the present processing method.

FIG. 14A is a diagram illustrating an example of a cross-sectional structure of the constituent member CP at an end of step STB.

FIG. 14B is a diagram illustrating an example of a cross-sectional structure of the constituent member CP at the end of step STB.

FIG. 14C is a diagram illustrating an example of a cross-sectional structure of the constituent member CP at the end of step STB.

### DETAILED DESCRIPTION

Hereinafter, each embodiment of the present disclosure will be described.

In an exemplary embodiment, there is provided a plasma processing method, including: (a) forming a precoat on a constituent member in a chamber, the precoat including a carbon-containing film; (b) providing a first substrate on a substrate support in the chamber; and (c) performing plasma processing on the first substrate, wherein the (a) includes (a1) supplying a first processing gas including a first gas in the chamber, the first gas containing carbon and hydrogen, (a2) supplying a source RF signal to form plasma from the first processing gas, and (a3) supplying a bias signal of 90 eV or more to the constituent member in the chamber.

In one exemplary embodiment, in the (a3), the bias signal is a bias DC signal or a bias RF signal of 40 MHz or less.

In one exemplary embodiment, the first gas is at least one of a hydrocarbon gas and a halogenated hydrocarbon gas.

In one exemplary embodiment, the first processing gas further includes at least one addition gas selected from the group consisting of a nitrogen-containing gas, a halogen-containing gas, and a boron-containing gas.

In one exemplary embodiment, a flow rate ratio of the addition gas to the first gas is 50 vol % or less.

In one exemplary embodiment, the first processing gas further includes a noble gas.

In one exemplary embodiment, the (a) further includes, after the (a1) to the (a3), (a4) reforming the precoat with plasma formed from a processing gas including at least one gas selected from the group consisting of a nitrogen-containing gas, a halogen-containing gas, and a boron-containing gas.

In one exemplary embodiment, the (a) is executed while a second substrate different from the first substrate is disposed on the substrate support.

In one exemplary embodiment, in the (a3), a bias signal of 120 eV or more is supplied to the constituent member in the chamber.

In one exemplary embodiment, the (a) is executed while a surface of the substrate support is exposed to a space in the chamber.

In one exemplary embodiment, in the (a3), a bias signal of 90 eV or more and 120 eV or less is supplied to the substrate support in the chamber.

In one exemplary embodiment, the constituent member in the chamber is a portion exposed to plasma in the (c).

In one exemplary embodiment, the constituent member in the chamber includes at least one selected from the group consisting of the substrate support, an upper electrode disposed to face the substrate support, an inner wall of the chamber, and a baffle plate.

In one exemplary embodiment, the method further includes (d) forming an intermediate film on a surface of the constituent member, before the (a), in which the (d) includes (d1) supplying a second processing gas including a second gas in the chamber, the second gas containing carbon and hydrogen, (d2) supplying a source RF signal to form plasma from the second processing gas, and (d3) supplying a bias signal having energy equal to or greater than the bias signal in the (a3) to the constituent member in the chamber.

In one exemplary embodiment, the second processing gas further includes at least one addition gas selected from the group consisting of a nitrogen-containing gas, a halogen-containing gas, and a boron-containing gas.

In one exemplary embodiment, the (d) further includes, after the (d1) to the (d3), (d4) supplying a third processing gas including a third gas in the chamber, the third gas containing carbon and hydrogen, and the third processing gas not including a nitrogen-containing gas, a halogen-containing gas, and a boron-containing gas, (d5) supplying a source RF signal to form plasma from the third processing gas, and (d6) supplying a bias signal of 90 eV or less to the constituent member in the chamber.

In one exemplary embodiment, between the (a) and the (b), a set is repeated once or a plurality of times, the set including (e1) supplying a third processing gas including a third gas in the chamber, the third gas containing carbon and hydrogen, and the third processing gas not including a nitrogen-containing gas, a halogen-containing gas, and a boron-containing gas, (e2) supplying a source RF signal to form plasma from the third processing gas, (e3) supplying a bias signal of 90 eV or less to the constituent member in the chamber, (e4) supplying the first processing gas in the chamber, (e5) supplying a source RF signal to form plasma from the first processing gas, and (e6) supplying a bias signal of 90 eV or more to the constituent member in the chamber.

In one exemplary embodiment, the (d) further includes, after the (d1) to the (d3), (d7) supplying a fourth processing gas in the chamber, the fourth processing gas including a fourth gas and an addition gas, the fourth gas containing carbon and hydrogen, and the addition gas being at least one selected from the group consisting of a nitrogen-containing gas, a halogen-containing gas, and a boron-containing gas, (d8) supplying a source RF signal to form plasma from the fourth processing gas, and (d9) supplying a bias signal of 120 eV or more to the constituent member in the chamber.

In one exemplary embodiment, between the (a) and the (b), a set is repeated once or a plurality of times, the set including (e7) supplying a fourth processing gas in the chamber, the fourth processing gas including a fourth gas and an addition gas, the fourth gas containing carbon and hydrogen, and the addition gas being at least one selected from the group consisting of a nitrogen-containing gas, a halogen-containing gas, and a boron-containing gas, (e8) supplying a source RF signal to form plasma from the fourth processing gas, (e9) supplying a bias signal of 120 eV or more to the constituent member in the chamber, (e10) supplying the first processing gas in the chamber, (e11) supplying a source RF signal to form plasma from the first processing gas, and (e12) supplying a bias signal of 90 eV or more to the constituent member in the chamber.

In an exemplary embodiment, there is provided a plasma processing method, including: (a) forming a precoat on a first constituent member in a chamber, the precoat including a carbon-containing film; (b) providing a first substrate on a substrate support in the chamber; and (c) performing plasma processing on the first substrate, wherein the (a) includes (a1) supplying a first processing gas including a first gas in the chamber, the first gas containing carbon and hydrogen, (a2) supplying a source RF signal to form plasma from the first processing gas, and (a3) supplying a bias signal to the first constituent member in the chamber and/or a second constituent member in the chamber, the second constituent member being different from the first constituent, and the (a) includes controlling at least one selected from the group consisting of a power of the bias signal, a frequency of the bias signal, a power of the source signal, a frequency of the source signal, and a pressure of the chamber such that an energy of ions incident on the first constituent member is 90 eV or more.

In one exemplary embodiment, the first processing gas further includes a noble gas, and the (a) further includes controlling a type and/or a flow rate of the noble gas such that the energy of the ions incident on the first constituent member is 90 eV or more.

In an exemplary embodiment, a plasma processing method, including: (a) forming an intermediate film on a first constituent member in a chamber; (b) forming a precoat including a carbon-containing film on the intermediate film; (c) providing a first substrate on a substrate support in the chamber; and (d) performing plasma processing on the first substrate, in which the (b) includes (b1) supplying a first processing gas including a first gas in the chamber, the first gas containing carbon and hydrogen, (b2) supplying a source RF signal to form plasma from the first processing gas, and (b3) supplying a first bias signal to the first constituent member in the chamber and/or a second constituent member in the chamber, the second constituent member being different from the first constituent member, and the (a) includes (a1) supplying a second processing gas including a second gas in the chamber, the second gas containing carbon and hydrogen, (a2) supplying a source RF signal to form plasma from the second processing gas, and (a3) supplying a second bias signal equal to or greater than the first bias signal to the first constituent member and/or the second constituent member in the chamber.

In one exemplary embodiment, the intermediate film includes a first intermediate film and a second intermediate film on the first intermediate film, and a thickness of the second intermediate film is equal to or greater than a thickness of the first intermediate film.

In an exemplary embodiment, a precoat forming method, including: (a1) supplying a first processing gas including a first gas in the chamber, the first gas containing carbon and hydrogen; (a2) supplying a source RF signal to form plasma from the first processing gas; and (a3) supplying a bias signal of 90 eV or more to a constituent member in the chamber, and forming a precoat including a carbon-containing film on the constituent member.

In one exemplary embodiment, there is provided a plasma processing apparatus, including: a chamber; a substrate support in the chamber; and a controller, wherein the controller is configured to execute (a) forming a precoat including a carbon-containing film on a constituent member in the chamber, (b) providing a first substrate on the substrate support in the chamber, and (c) performing plasma processing on the first substrate, and the (a) includes (a1) supplying a first processing gas including a first gas in the chamber, the first gas containing carbon and hydrogen, (a2) supplying a source RF signal to form plasma from the first processing gas, and (a3) supplying a bias signal of 90 eV or more to the constituent member in the chamber.

Hereinafter, each embodiment of the present disclosure will be described in detail with reference to the drawings. In each drawing, the same or similar elements will be given the same reference numerals, and repeated descriptions will be omitted. Unless otherwise specified, a positional relationship such as up, down, left, and right will be described based on a positional relationship illustrated in the drawings. A dimensional ratio in the drawings does not indicate an actual ratio, and the actual ratio is not limited to the ratio illustrated in the drawings.

### <Configuration Example of Plasma Processing Apparatus>

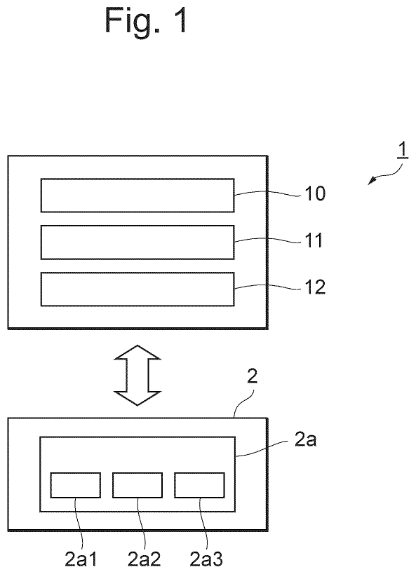

FIG. 1 is a diagram for describing a configuration example of a plasma processing apparatus. In an embodiment, a plasma processing apparatus 1 is an example of a substrate processing apparatus. The plasma processing apparatus 1 includes a controller 2, a plasma processing chamber 10, a substrate support 11, and a plasma generator 12. The plasma processing chamber 10 has a plasma processing space. In addition, the plasma processing chamber 10 has at least one gas supply port for supplying at least one processing gas to the plasma processing space and at least one gas exhaust port for exhausting the gas from the plasma processing space. The gas supply port is connected to a gas supply 20 which is described later, and the gas exhaust port is connected to an exhaust system 40 which is described later. The substrate support 11 is disposed in the plasma processing space and has a substrate support surface for supporting a substrate.

The plasma generator 12 is configured to form a plasma from at least one processing gas supplied into the plasma processing space. The plasma formed in the plasma processing space may be a capacitively coupled plasma (CCP), an inductively coupled plasma (ICP), an electron-cyclotron-resonance plasma (ECR plasma), a helicon wave plasma (HWP), a surface wave plasma (SWP), or the like. Further, various types of plasma generators including an alternating current (AC) plasma generator and a direct current (DC) plasma generator may be used. In an embodiment, an AC signal (AC power) used in the AC plasma generator has a frequency in the range of 100 KHz to 10 GHZ. Therefore, the AC signal includes a radio frequency (RF) signal and a microwave signal. In an embodiment, an RF signal has a frequency in the range of 100 kHz to 150 MHz.

The controller 2 processes a computer-executable instruction that causes the plasma processing apparatus 1 to execute various steps described in the present disclosure. The controller 2 may be configured to control each element of the plasma processing apparatus 1 to execute the various steps described here. In an embodiment, a part or all of the controller 2 may be configured as a system outside the plasma processing apparatus 1. The controller 2 may include a processor 2a1, a storage 2a2, and a communication interface 2a3. The controller 2 is realized by, for example, a computer 2a. The processor 2a1 may be configured to read out a program from the storage 2a2 and to execute the read-out program to perform various control operations. This program may be stored in the storage 2a2 in advance, or may be acquired via a medium when necessary. The acquired program is stored in the storage 2a2, is read out from the storage 2a2, and executed by the processor 2a1. The medium may be various storage media readable by the computer 2a, or may be a communication line connected to the communication interface 2a3. The processor 2a1 may be a central processing unit (CPU). The storage 2a2 may include a random access memory (RAM), a read only memory (ROM), a hard disk drive (HDD), a solid state drive (SSD), or a combination thereof. The communication interface 2a3 may communicate with each element of the plasma processing apparatus 1 via a communication line such as a local area network (LAN). The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium such as a CD-ROM or DVD, and/or the memory of a FPGA or ASIC.

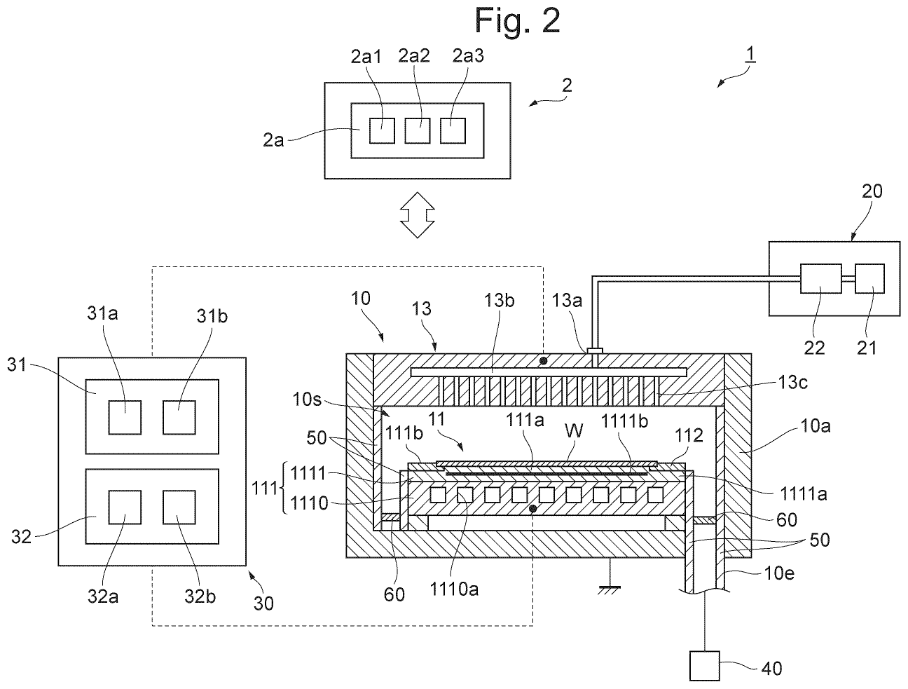

Hereinafter, a configuration example of the capacitively coupled plasma processing apparatus as an example of the plasma processing apparatus 1 will be described. FIG. 2 is a diagram for describing a configuration example of the capacitively coupled plasma processing apparatus.

The capacitively coupled plasma processing apparatus 1 includes the controller 2, the plasma processing chamber 10, the gas supply 20, a power supply 30, and the exhaust system 40. In addition, the plasma processing apparatus 1 includes the substrate support 11 and a gas introducer. The gas introducer is configured to introduce at least one processing gas into the plasma processing chamber 10. The gas introducer includes a shower head 13. The substrate support 11 is disposed in the plasma processing chamber 10. The shower head 13 is disposed above the substrate support 11. In an embodiment, the shower head 13 configures at least a part of a ceiling of the plasma processing chamber 10. The plasma processing chamber 10 has a plasma processing space 10s defined by the shower head 13, a side wall 10a of the plasma processing chamber 10, and the substrate support 11. The plasma processing chamber 10 is grounded. The shower head 13 and the substrate support 11 are electrically insulated from a housing of the plasma processing chamber 10.

The substrate support 11 includes a main body 111 and a ring assembly 112. The main body 111 has a center region 111a for supporting the substrate W and an annular region 111b for supporting the ring assembly 112. A wafer is an example of the substrate W. The annular region 111b of the main body 111 surrounds the center region 111a of the main body 111 in plan view. The substrate W is disposed on the center region 111a of the main body 111, and the ring assembly 112 is disposed on the annular region 111b of the main body 111 to surround the substrate W on the center region 111a of the main body 111. Therefore, the center region 111a is also referred to as a substrate support surface for supporting the substrate W, and the annular region 111b is also referred to as a ring support surface for supporting the ring assembly 112.

In an embodiment, the main body 111 includes a base 1110 and an electrostatic chuck 1111. The base 1110 includes a conductive member. The conductive member of the base 1110 may function as a lower electrode. The electrostatic chuck 1111 is disposed on the base 1110. The electrostatic chuck 1111 includes a ceramic member 1111a and an electrostatic electrode 1111b disposed in the ceramic member 1111a. The ceramic member 1111a has the center region 111a. In an embodiment, the ceramic member 1111a also has the annular region 111b. Another member that surrounds the electrostatic chuck 1111 may have the annular region 111b, such as an annular electrostatic chuck or an annular insulating member. In this case, the ring assembly 112 may be disposed on the annular electrostatic chuck or the annular insulating member, or may be disposed on both the electrostatic chuck 1111 and the annular insulating member. Further, at least one RF/DC electrode coupled to an RF power supply 31 and/or a DC power supply 32, which will be described later, may be disposed in the ceramic member 1111a. In this case, at least one RF/DC electrode functions as the lower electrode. In a case where a bias RF signal and/or a DC signal, which will be described later, are supplied to at least one RF/DC electrode, the RF/DC electrode is also referred to as a bias electrode. The conductive member of the base 1110 and at least one RF/DC electrode may function as a plurality of lower electrodes. Further, the electrostatic electrode 1111b may function as the lower electrode. Therefore, the substrate support 11 includes at least one lower electrode.

The ring assembly 112 includes one or a plurality of annular members. In an embodiment, one or the plurality of annular members includes one or a plurality of edge rings and at least one cover ring. The edge ring is formed of a conductive material or an insulating material, and the cover ring is formed of an insulating material.

In addition, the substrate support 11 may include a temperature-controlled module configured to adjust at least one of the electrostatic chuck 1111, the ring assembly 112, and the substrate to a target temperature. The temperature-controlled module may include a heater, a heat transfer medium, a flow passage 1110a, or a combination thereof. A heat transfer fluid such as brine or a gas flows in the flow passage 1110a. In an embodiment, the flow passage 1110a is formed in the base 1110, and one or a plurality of heaters is disposed in the ceramic member 1111a of the electrostatic chuck 1111. Further, the substrate support 11 may include a heat transfer gas supply configured to supply the heat transfer gas to a gap between a back surface of the substrate W and the center region 111a.

The shower head 13 is configured to introduce at least one processing gas from the gas supply 20 into the plasma processing space 10s. The shower head 13 has at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s from the gas introduction ports 13c. In addition, the shower head 13 includes at least one upper electrode. In addition to the shower head 13, the gas introducer may include one or a plurality of side gas injectors (SGI) attached to one or a plurality of opening portions formed on the side wall 10a.

The gas supply 20 may include at least one gas source 21 and at least one flow rate controller 22. In an embodiment, the gas supply 20 is configured to supply at least one processing gas to the shower head 13 from each corresponding gas source 21 via each corresponding flow rate controller 22. Each flow rate controller 22 may include, for example, a mass flow controller or a pressure-controlled flow rate controller. Further, the gas supply 20 may include at least one flow rate modulation device that modulates or pulses a flow rate of at least one processing gas.

The power supply 30 includes the RF power supply 31 coupled to the plasma processing chamber 10 via at least one impedance matching circuit. The RF power supply 31 is configured to supply at least one RF signal (RF power) to at least one lower electrode and/or at least one upper electrode. As a result, plasma is formed from at least one processing gas supplied to the plasma processing space 10s. Therefore, the RF power supply 31 may function as at least a part of the plasma generator 12. Further, by supplying the bias RF signal to at least one lower electrode, a bias potential is generated in the substrate W, and an ion component in the formed plasma is able to be drawn into the substrate W.

In an embodiment, the RF power supply 31 includes a first RF generator 31a and a second RF generator 31b. The first RF generator 31a is coupled to at least one lower electrode and/or at least one upper electrode via at least one impedance matching circuit and is configured to generate a source RF signal (source RF power) for plasma formation. In an embodiment, the source RF signal has a frequency in a range of 10 MHz to 150 MHz. In an embodiment, the first RF generator 31a may be configured to generate a plurality of source RF signals having different frequencies. The generated one or plurality of source RF signals is supplied to at least one lower electrode and/or at least one upper electrode.

The second RF generator 31b is coupled to at least one lower electrode via at least one impedance matching circuit and is configured to generate the bias RF signal (bias RF power). The frequency of the bias RF signal may be the same as or different from the frequency of the source RF signal. In an embodiment, the bias RF signal has a frequency lower than the frequency of the source RF signal. In an embodiment, the bias RF signal has a frequency in a range of 100 KHz to 60 MHz. In an embodiment, the second RF generator 31b may be configured to generate a plurality of bias RF signals having different frequencies. The generated one or plurality of bias RF signals is supplied to at least one lower electrode. In addition, in various embodiments, at least one of the source RF signal and the bias RF signal may be pulsed.

In addition, the power supply 30 may include the DC power supply 32 coupled to the plasma processing chamber 10. The DC power supply 32 includes a first DC generator 32a and a second DC generator 32b. In an embodiment, the first DC generator 32a is connected to at least one lower electrode, and is configured to generate a first DC signal. The generated first DC signal is applied to at least one lower electrode. In an embodiment, the second DC generator 32b is connected to at least one upper electrode and is configured to generate a second DC signal. The generated second DC signal is applied to at least one upper electrode.

In various embodiments, the first and second DC signals may be pulsed. In this case, a sequence of voltage pulses is applied to at least one lower electrode and/or at least one upper electrode. The voltage pulse may have a pulse waveform having a rectangular shape, a trapezoidal shape, a triangular shape, or a combination thereof. In an embodiment, a waveform generator for generating the sequence of voltage pulses from the DC signal is connected between the first DC generator 32a and at least one lower electrode. Therefore, the first DC generator 32a and the waveform generator configure the voltage pulse generator. In a case where the second DC generator 32b and the waveform generator configure the voltage pulse generator, the voltage pulse generator is connected to at least one upper electrode. The voltage pulse may have a positive polarity or a negative polarity. In addition, the sequence of voltage pulses may include one or a plurality of positively-polarized voltage pulses and one or a plurality of negatively-polarized voltage pulses in one cycle. The first and second DC generators 32a and 32b may be provided in addition to the RF power supply 31, and the first DC generator 32a may be provided instead of the second RF generator 31b.

The exhaust system 40 may be connected to, for example, a gas exhaust port 10e provided at a bottom portion of the plasma processing chamber 10. The exhaust system 40 may include a pressure regulating valve and a vacuum pump. A pressure in the plasma processing space 10s is regulated by the pressure regulating valve. The vacuum pump may include a turbo molecular pump, a dry pump, or a combination thereof.

In an embodiment, the plasma processing chamber 10 may include a shield 50. The shield 50 may be provided to be attachable and detachable in the side wall 10a of the plasma processing chamber 10. The shield 50 defines a part of the plasma processing space 10s. The shield 50 may suppress the by-product of etching from being attached to the side wall 10a. The shield 50 may be further provided to be attachable and detachable in an outer periphery of the substrate support 11.

In an embodiment, the plasma processing chamber 10 may include a baffle plate 60. The baffle plate 60 separates the inside of the plasma processing chamber 10 into the plasma processing space 10s and an exhaust space including a region in the vicinity of the gas exhaust port 10e. The baffle plate 60 may suppress the plasma from entering the exhaust space on a downstream side of the baffle plate 60. The baffle plate 60 may be provided between the substrate support 11 and the side wall 10a of the plasma processing chamber 10 in the vicinity of the bottom portion of the plasma processing chamber 10. The baffle plate 60 may be an annular plate body. The baffle plate 60 may be provided with an opening portion consisting of a through-hole, a slit, or the like for exhausting air.

### <Example of Plasma Processing Method>

A plasma processing method according to an exemplary embodiment of the present disclosure (hereinafter, also referred to as “the present processing method”) will be described. The processing in each step may be executed by the plasma processing apparatus 1 illustrated in FIGS. 1 and 2. In the following, a case where the controller 2 controls each unit of the capacitively coupled plasma processing apparatus 1 (see FIG. 2) to execute the present processing method will be described as an example.

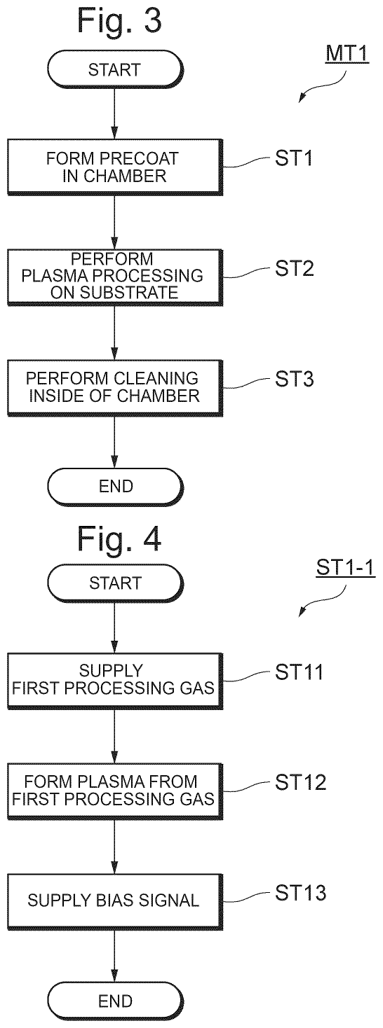

FIG. 3 is a flowchart illustrating an example of the present processing method (hereinafter, also referred to as a “method MT1”). As illustrated in FIG. 3, the method MT1 includes step ST1 of forming a precoat and step ST2 of performing plasma processing on the substrate. The method MT1 may further include step ST3 of performing cleaning.

First, in step ST1, the precoat is formed on the constituent member CP in the plasma processing chamber 10 (hereinafter, also simply referred to as “chamber 10”). The precoat is able to provide protection to the constituent member CP in the plasma processing in step ST2. The precoat may be formed on a surface of the constituent member CP in the chamber 10, which is exposed to the plasma processing space 10s, that is, a surface exposed to the plasma (hereinafter, also referred to as a “plasma exposure surface”). In an example, the constituent member CP on which the precoat is formed is any one or more members of the shower head 13, the edge ring of the ring assembly 112, the side wall 10a, the shield 50, and the baffle plate 60, or a part of the member. In an example, the precoat may be formed on the entire plasma exposure surface. In an example, the precoat may be formed on the plasma exposure surface excluding the substrate support 11. The details of step ST1 will be described later.

Next, in step ST2, the plasma processing is performed on a first substrate W. The first substrate W is transported in the chamber 10 by a transport apparatus and is disposed in the center region 111a of the substrate support 11. The first substrate W is adsorbed and held on the substrate support 11 using the electrostatic chuck 1111. Then, the plasma processing is performed on the first substrate W. In an example, the plasma processing includes etching processing of etching the film on the first substrate W using plasma. In an example, the plasma processing includes film forming processing of forming a film on the first substrate W using plasma. After the plasma processing, the first substrate W is transported outside the chamber 10 by the transport apparatus.

Next, in step ST3, the inside of the chamber 10 is cleaned. In an embodiment, the cleaning gas is introduced into the plasma processing space 10s from the gas supply 20 via the shower head 13. The cleaning gas may be, for example, an oxygen-containing gas. Next, plasma is formed from the cleaning gas. By the plasma, a part or all of the reaction product attached to the constituent members CP of the chamber 10 in step ST2 may be removed. In addition, a part or all of the film (precoat or an intermediate film described later) formed on the constituent member CP of the chamber 10 in step ST1 is able to be removed by the plasma. In a case where a plurality of substrates W is processed as one unit (lot), step ST3 may be executed after step ST2 is executed for one or the plurality of substrates W included in the lot. That is, step ST3 may be executed after step ST2 is executed a plurality of times.

In the method MT1, the film quality of the precoat is controlled in step ST1. Hereinafter, an example of step ST1 will be described with reference to FIGS. 4 to 7.

FIG. 4 is a flowchart illustrating a first example of step ST1 (hereinafter, also referred to as “step ST1-1”). In step ST1-1, the precoat including a carbon-containing film is formed on the constituent members CP in the chamber 10.

As illustrated in FIG. 4, step ST1-1 includes step ST11 of supplying the first processing gas to the chamber 10, step ST12 of forming plasma from the first processing gas, and step ST13 of supplying a bias signal to the chamber 10. Step ST13 may be started at the same time as step ST12, may be started during the execution of step ST12, or may be started after the execution of step ST12.

### (Step ST11)

First, in step ST11, the first processing gas is supplied from the gas supply 20 into the plasma processing space 10s of the chamber 10. The first processing gas includes a first gas containing carbon and hydrogen. In an embodiment, the first gas containing carbon and hydrogen is at least one of a hydrocarbon gas and a halogenated hydrocarbon gas. The hydrocarbon gas may be, for example, CH₄ gas, C₂H₂ gas, C₂H₄ gas, or the like. The halogenated hydrocarbon gas is a gas in which a hydrogen atom in a hydrocarbon molecule is substituted with a halogen, and may be, for example, a CHF-based gas, a CHCl-based gas, a CHBr-based gas, or the like.

In an embodiment, the first processing gas may include a first addition gas consisting of a nitrogen-containing gas. The first addition gas may be, for example, an N₂ gas, an NF₃ gas, an NH₃ gas, or the like. In an embodiment, the first processing gas may include a second addition gas consisting of a halogen-containing gas and/or a boron-containing gas. The second addition gas may be, for example, a CF₄ gas, a Cl₂ gas, an HBr gas, a BCls gas, a BF₃ gas, or the like. In an embodiment, a flow rate ratio of the addition gas (the first addition gas and the second addition gas) to the first gas may be 50 vol % or less.

In an embodiment, the first processing gas may further include noble gases such as Ar gas, He gas, and Kr gas.

### (Step ST12)

In step ST12, the source RF signal is supplied from the first RF generator 31a to the lower electrode of the substrate support 11 and/or the upper electrode of the shower head 13. An RF electric field is generated between the shower head 13 and the substrate support 11, and the plasma is formed from the first processing gas in the plasma processing space 10s. The carbon in the plasma is deposited on the surface of the constituent component CP in the chamber 10. As a result, the precoat is formed on the plasma exposure surface of the constituent component CP. The precoat is a carbon-containing film containing carbon. In an embodiment, the power of the source RF signal is 0.1 KW or more and 10 KW or less. In an embodiment, the pressure in the chamber 10 is controlled to be 5 m Torr or more and 1000 m Torr or less.

### (Step ST13)

In step ST13, the bias signal is supplied to the constituent member CP. In an embodiment, the bias signal may be a bias RF signal. In an example, the bias RF signal is supplied from the second RF generator 31b to the lower electrode of the substrate support 11. The bias RF signal may have a frequency of 40 MHz or less. In an embodiment, the bias signal may be a bias DC signal. In an example, the bias DC signal is supplied from the first DC generator 32a to the lower electrode of the substrate support 11. In an example, the bias DC signal is supplied from the second DC generator 32b to the upper electrode of the shower head 13. The bias DC signal may be negatively polarized. In an embodiment, the pressure in the chamber 10 is controlled to be 5 m Torr or more and 1000 m Torr or less.

In an embodiment, in step ST1 (step ST11 to step ST13), at least one selected from the group consisting of the power (electric power or voltage) of the bias signal, the frequency of the bias signal, the power of the source RF signal, the frequency of the source RF signal, and the pressure in the chamber 10 may be controlled such that the energy of the ions incident on the constituent member CP is 90 eV or more. In an example, in a case where the precoat is formed on the constituent member CP, a bias signal of 90 eV or more may be supplied to the constituent member CP. In a case where the first processing gas includes a gas other than the first gas, the energy of the ions incident on the first constituent member may be adjusted by controlling the type and/or the flow rate of the gas. In an example, in a case where the first processing gas further includes a noble gas, the energy of the ions incident on the constituent member CP may be adjusted to 90 eV or more by adjusting the type and/or the flow rate of the noble gas.

By supplying the bias signal to the constituent member CP, ions in the plasma are driven into the precoat formed on the surface of the constituent component CP. The kinetic energy of the ions is converted into thermal energy, and the binding state of the carbon-containing film in the precoat is changed. In an example, in a case where the energy of the ions incident on the constituent member CP is 90 eV or more, the conductivity and the film density of the precoat may be increased. The improvement of conductivity is considered to be due to an increase in the proportion of carbon (graphite) of the SP² bond. In addition, it is considered that the increase in the film density is due to a decrease in the hydrogen ratio in the film.

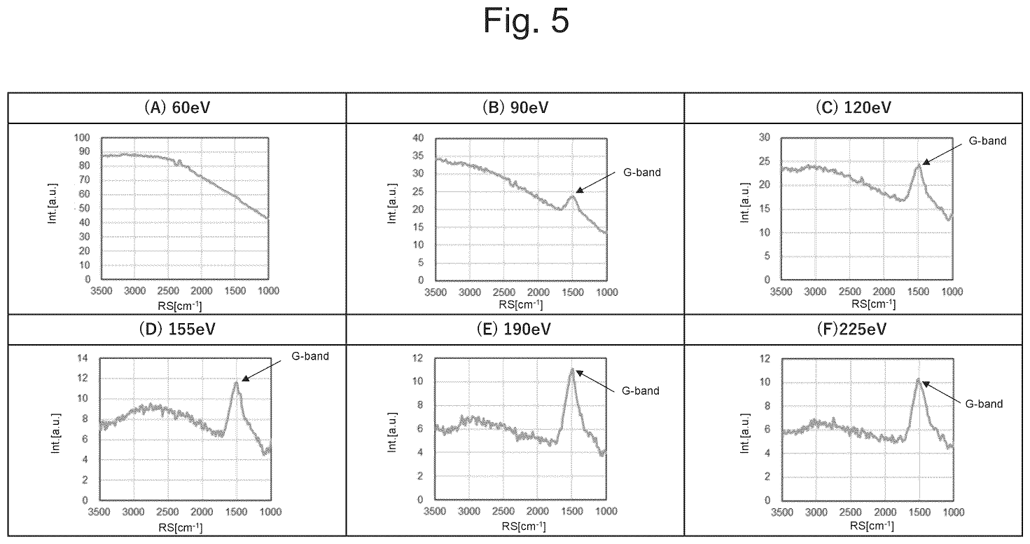

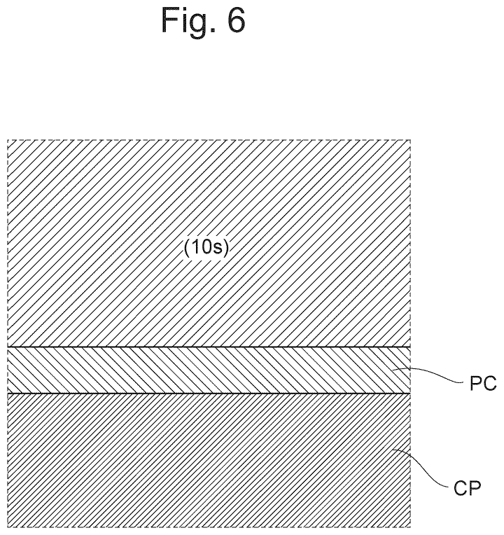

FIG. 5 is a diagram illustrating an example of a relationship between the energy of the ions incident on the constituent member (the energy of the bias signal supplied to the constituent member CP) and a Raman spectrum. In FIG. 5, (A) is an example of the Raman spectrum of the carbon-containing film in the precoat formed in a case where the energy of the bias signal supplied to the chamber 10 is 60 eV. Similarly, (B) to (F) are examples of Raman spectra in a case where the energies of the bias signals are 90 eV, 120 eV, 155 eV, 190 eV, and 225 eV, respectively. In the example illustrated in FIG. 5, when the energy of the bias signal is 90 eV or more ((B) to (F) of FIG. 5), a G band appears near 1500 cm⁻¹. On the other hand, in a case where the energy of the bias signal is 60 eV ((A) of FIG. 5), the G band does not appear. In this example, it is considered that the energy of the bias signal is set to 90 eV or more, and thus the proportion of carbon (graphite) having a sp² bond may be increased as the hydrogen ratio in the film decreases.

In a case where the first processing gas further includes the first addition gas (nitrogen-containing gas), the conductivity of the precoat may be further increased. The reason for this is considered to be that the carrier density is improved by doping nitrogen in the carbon-containing film constituting the precoat. In addition, it is considered that this is because the proportion of carbon (graphite) having the sp² bond in the carbon-containing film increases.

In a case where the first processing gas includes the second addition gas (halogen-containing gas and/or boron-containing gas), the conductivity of the precoat may be further increased.

In an embodiment, after step ST12 or step ST13, a step of forming plasma using the first addition gas and/or the second addition gas to reform the precoat may be further executed. As a result, the conductivity and/or the film density of the precoat may be further increased. In this case, the first processing gas may not include the addition gas (the first addition gas and/or the second addition gas).

FIG. 6 is a diagram illustrating an example of a cross-sectional structure of the constituent member CP at an end of step ST13. As illustrated in FIG. 6, a precoat PC is formed on the plasma exposure surface of the constituent member CP. The precoat PC is a carbon-containing film containing carbon. In an embodiment, a film thickness of the precoat PC is 10 nm or more and 1500 nm or less. In FIG. 6, the constituent member CP may be the shower head 13, the edge ring of the ring assembly 112, the side wall 10a, the shield 50, and/or the baffle plate 60. In an example, the constituent member CP is made of a silicon-containing material such as silicon or silicon carbide. In an example, the constituent member CP is made of a metal material such as aluminum.

The conductivity of the precoat may be improved by the processing in step ST13. Therefore, in the plasma processing in step ST2, desired conductivity may be secured between the plasma and the constituent member CP. As a result, abnormal discharge during the plasma processing is suppressed, and generation of dust in the chamber 10 may be suppressed. In addition, by the processing in step ST13, the film density of the precoat is improved, and the resistance to the plasma may be improved. Therefore, in the plasma processing in step ST2, the weakening of the precoat is suppressed, and the generation of dust in the chamber 10 may be suppressed.

By the way, in step ST2, the first substrate W is disposed on the substrate support 11. Therefore, the plasma exposure surface of the substrate support 11 may be suppressed from being damaged by the plasma, regardless of the presence or absence of the precoat. In addition, when the conductivity of the plasma exposure surface of the substrate support 11 is excessively increased by the precoat, the adsorption force between the substrate support 11 and the first substrate W may be reduced. In an embodiment, in step ST1, the precoat does not need to be formed on the plasma exposure surface of the substrate support 11. In addition, in an embodiment, in step ST1, the precoat having a film quality different from that of the other plasma exposure surface may be formed on the plasma exposure surface of the substrate support 11.

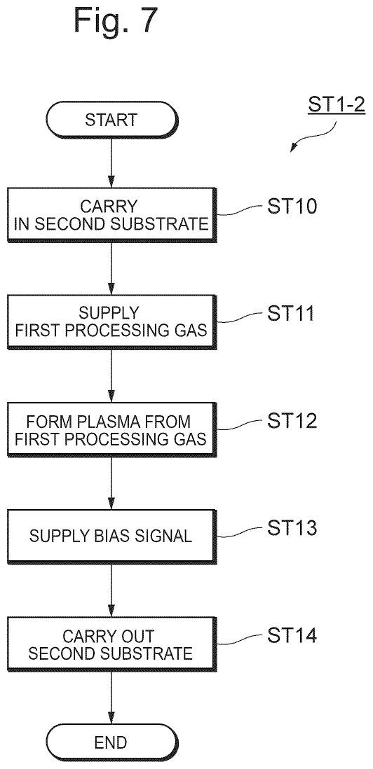

FIG. 7 is a flowchart illustrating a second example of step ST1 (hereinafter, also referred to as “step ST1-2”). The second example is an example in which the precoat is formed on the plasma exposure surface except for the plasma exposure surface of the substrate support 11. As illustrated in FIG. 7, step ST1-2 includes step ST10 of carrying a second substrate W2 in the chamber 10, step ST11 of supplying the first processing gas to the chamber 10, step ST12 of forming plasma from the first processing gas, step ST13 of supplying the bias signal to the constituent member CP, and step ST14 of carrying the second substrate W2 out of the chamber 10.

In step ST10, the second substrate W2 is transported in the chamber 10 by the transport apparatus. The second substrate W2 is disposed on the center region 111a of the substrate support 11. The second substrate W2 is adsorbed and held on the substrate support 11 using the electrostatic chuck 1111. The second substrate W2 is a substrate different from the first substrate that is subjected to the plasma processing in step ST2. The second substrate W2 may be a dummy substrate. The dummy substrate may have the same dimensions and shape as the first substrate.

Steps ST11 to ST13 are the same as those of the first example described using FIG. 4. However, in step ST12 and step ST13, the precoat is not formed on the plasma exposure surface of the substrate support 11 on which the second substrate W2 is disposed.

In step ST14, the second substrate W2 is carried out of the chamber 10 by the transport apparatus.

In the second example of step ST1, the precoat in which the conductivity and the film density are increased is able to be formed on a portion of the plasma exposure surface of the constituent member CP, excluding the substrate support 11.

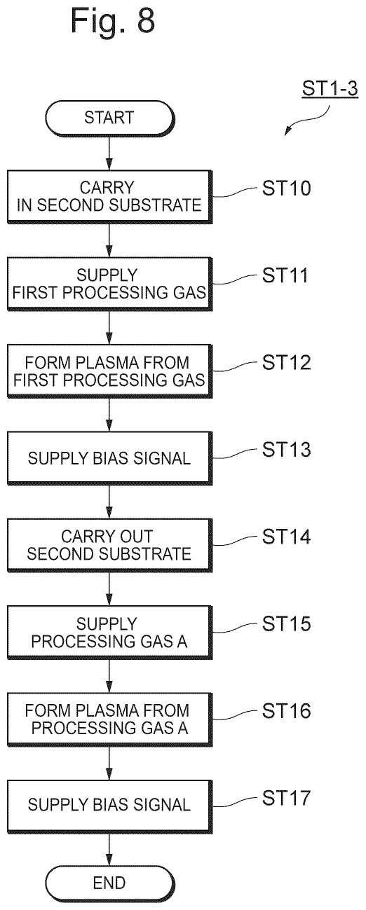

FIG. 8 is a flowchart illustrating a third example of step ST1 (hereinafter, also referred to as “step ST1-3”). The third example is an example in which the precoat having a film quality different from that of the other plasma exposure surfaces is formed on the plasma exposure surface of the substrate support 11. As illustrated in FIG. 8, step ST1-3 includes, similarly to the second example (step ST1-2), the steps ST10 to ST14. In addition, step ST1-3 includes step ST15 of supplying the processing gas A to the chamber 10, step ST16 of forming plasma from the processing gas A, and step ST17 of supplying the bias signal to the constituent member CP after step ST14 is executed.

Steps ST10 to ST14 are the same as those in the second example (step ST1-2), and the description thereof will be omitted. Steps ST15 to ST17 are steps after the second substrate W2 is carried out from the chamber 10. That is, step ST15 to step ST17 are executed while the surface of the substrate support 11 is exposed to the plasma processing space 10s.

In step ST15, the processing gas A is supplied from the gas supply 20 into the plasma processing space 10s of the chamber 10. The processing gas A includes the above-described first gas. In an embodiment, the processing gas A may be the same as the first processing gas. In an embodiment, the processing gas A may have a different type or composition of gas from the first processing gas. For example, the processing gas A may not include the first addition gas and/or the second addition gas. In addition, for example, the processing gas A may contain the addition gas at a flow rate lower than the flow rate of the addition gas (the first addition gas and/or the second addition gas) contained in the first processing gas.

Step ST16 is executed in the same manner as step ST12. In step ST16, a second precoat is formed on the plasma exposure surface of the substrate support 11. In an embodiment, the power of the source RF signal may be the same as the power, or may be smaller than the power of the source RF signal in step ST12.

Step ST17 is executed in the same manner as step ST13. However, in step ST17, the energy of the ions incident on the constituent member CP (the energy of the bias signal supplied to the constituent member CP) may be lower than the energy of the ions incident on the constituent member CP in step ST13 (the energy of the bias signal supplied to the constituent member CP). In an example, the energy of the ions incident on the constituent member CP is adjusted to 90 eV or more and 120 eV or less. As a result, the film quality of the second precoat may be different from the film quality of the precoat formed in step ST13. In an example, the conductivity of the second precoat is lower than that of the precoat formed in step ST13.

In the third example of step ST1, the second precoat having lower conductivity than the precoat PC may be formed on the plasma exposure surface of the substrate support 11.

In an embodiment, step ST1-3 may include a step of covering a part or all of the portion where the precoat is formed with a shield member or the like, between step ST14 and step ST15. In this case, the second precoat is not formed on the portion (the portion on which the precoat is formed) covered with the shield member.

The method of forming the precoat having a film quality different from that of the other plasma exposure surface on the plasma exposure surface of the substrate support 11 is not limited to the third example described above. For example, the following configuration may be adopted. First, in step ST1, steps ST15 to ST17 are first executed, and the second precoat is formed on the plasma exposure surface including the substrate support 11. Next, after the second substrate is carried in on the substrate support 11 by executing step ST10, a step of cleaning the inside of the chamber 10 is executed. As a result, the second precoat formed on the plasma exposure surface excluding the substrate support 11 covered with the second substrate is removed. On this, steps ST11 to ST14 are executed. As described above, the second precoat is formed on the plasma exposure surface of the substrate support 11, and the precoat PC is formed on the remaining plasma exposure surfaces.

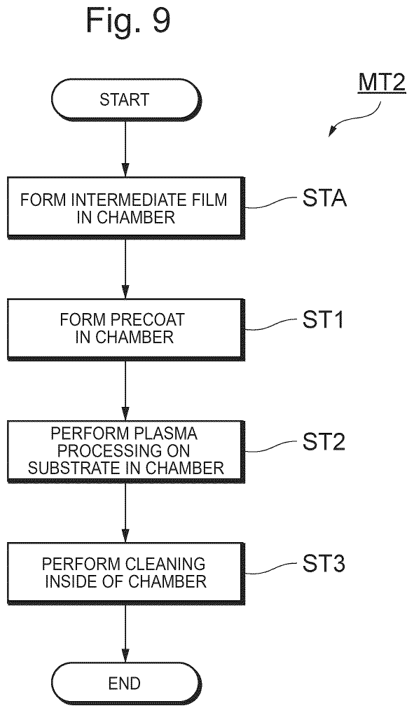

FIG. 9 is a flowchart illustrating another example of the present processing method (hereinafter, also referred to as a “method MT2”). As illustrated in FIG. 9, the method MT2 includes step STA of forming an intermediate film in the chamber, step ST1 of forming the precoat in the chamber, and step ST2 of performing the plasma processing on the substrate. The method MT2 may further include step ST3 of performing cleaning inside of the chamber 10.

The method MT2 is different from the method MT1 in that the method MT2 includes step STA of forming the intermediate film before forming the precoat in the chamber. Steps ST1 to ST3 are the same as those in the method MT1 except that steps ST1 to ST3 are executed while the intermediate film is formed on the constituent member CP. For example, in step ST1, the precoat is formed on the intermediate film formed on the constituent member CP. Step ST1 may be continuously executed from step STA. For example, the processing gas (the second processing gas/the third processing gas) used in step STA and the first processing gas used in step ST1 may be the same. In this case, step ST1 may be executed by changing only the energy of the bias signal while maintaining the state in the chamber (the state in which the processing gas is supplied and the plasma is formed) in step STA as it is. In addition, for example, the processing gas (the second processing gas/the third processing gas) used in step STA and the first processing gas used in step ST1 may be different from each other. In this case, step ST1 may be executed by changing only the processing gas while the supply of the source RF signal and the bias signal is maintained to be the same as that in step STA.

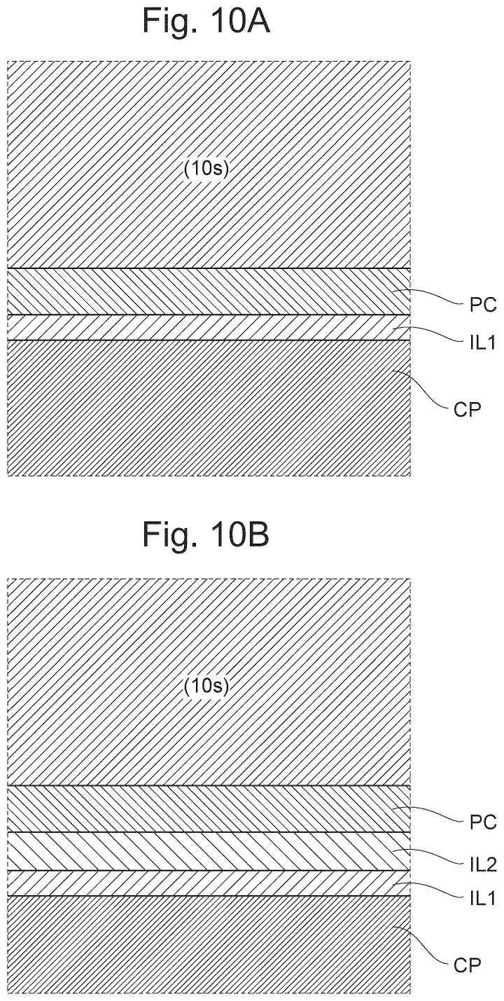

FIGS. 10A and 10B are diagrams illustrating examples of the cross-sectional structure of the constituent member CP at the end of step STA and step ST1, respectively. As illustrated in FIG. 10A, a first intermediate film IL1 may be formed in step STA, and the precoat PC may be formed on the first intermediate film IL1 in step ST1. In an embodiment, the first intermediate film IL1 may function as an adhesion layer for closely attaching the precoat PC to the constituent member CP. The film thickness of the precoat PC may be equal to or greater than the film thickness of the intermediate film IL1. In an example, the film thickness of the first intermediate film IL1 is 1 nm or more and 10 nm or less. In an example, the film thickness of the precoat PC is 10 nm or more and 1500 nm or less.

As illustrated in FIG. 10B, the first intermediate film IL1 and the second intermediate film IL2 are formed in step STA, and then the precoat PC may be formed on the second intermediate film IL2 in step ST1. In an embodiment, the first intermediate film IL1 may function as an adhesion layer for closely attaching the precoat PC to the constituent member CP. In an embodiment, the second intermediate film IL2 may function as a stress relaxing layer that relaxes the stress applied to an interface from the precoat PC to the constituent member CP. The film thickness of the second intermediate film IL2 may be equal to or greater than the film thickness of the first intermediate film IL1. The film thickness of the precoat PC may be equal to or greater than the film thickness of the first intermediate film IL1 or may be equal to or greater than the film thickness of the second intermediate film IL2. In an example, the film thickness of the first intermediate film IL1 is 1 nm or more and 10 nm or less. In an example, the film thickness of the second intermediate film IL2 is 10 nm or more and 100 nm or less. In an example, the film thickness of the precoat PC is 10 nm or more and 1500 nm or less.

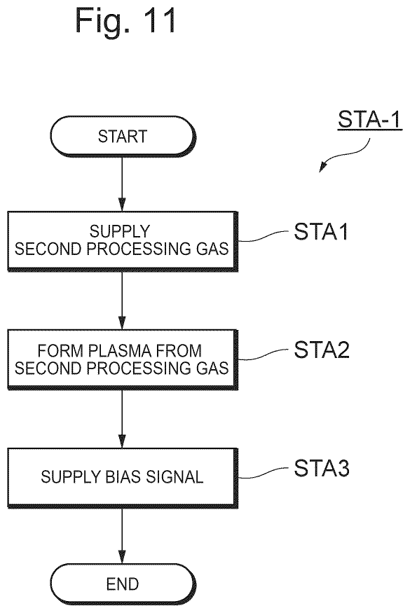

FIG. 11 is a flowchart illustrating a first example of step STA (hereinafter, also referred to as “step STA-1”). Step STA-1 is an example of a step of forming the first intermediate film IL1 illustrated in FIG. 10A. That is, in step STA-1, the first intermediate film IL1 is formed on the constituent member CP in the chamber 10.

As illustrated in FIG. 11, step STA-1 includes step STA1 of supplying the second processing gas to the chamber 10, step STA2 of forming plasma from the second processing gas, and step STA3 of supplying the bias signal to the constituent member CP. Step STA3 may be started at the same time as step STA2, may be started during the execution of step STA2, or may be started after the execution of step STA2.

### (Step STA1)

First, in step STA1, the second processing gas is supplied from the gas supply 20 into the plasma processing space 10s of the chamber 10. The second processing gas includes a second gas containing carbon and hydrogen. In an embodiment, the second gas is a gas of at least one of a hydrocarbon gas or a halogenated hydrocarbon gas. The hydrocarbon gas may be, for example, CH₄ gas, C₂H₂ gas, C₂H₄ gas, or the like. The halogenated hydrocarbon gas is a gas in which a hydrogen atom in a hydrocarbon molecule is substituted with a halogen, and may be, for example, a CHF-based gas, a CHCl-based gas, a CHBr-based gas, or the like.

In an embodiment, the second processing gas may further include the above-described addition gas (the first addition gas and/or the second addition gas). In an embodiment, the flow rate ratio of the addition gas to the second gas may be 50 vol % or less.

In an embodiment, the second processing gas may further include noble gases such as Ar gas, He gas, and Kr gas.

In an embodiment, the second processing gas may be the same gas as the first processing gas.

### (Step STA2)

In step STA2, the source RF signal is supplied from the first RF generator 31a to the lower electrode of the substrate support 11 and/or the upper electrode of the shower head 13. As a result, a RF electric field is generated between the shower head 13 and the substrate support 11, and plasma is formed from the second processing gas in the plasma processing space 10s. The carbon in the plasma is deposited on the surface of the constituent component CP in the chamber 10. As a result, the first intermediate film IL1 is formed on the plasma exposure surface of the constituent component CP. The first intermediate film IL1 is a carbon-containing film containing carbon. In an embodiment, the power of the source RF signal is 0.1 KW or more and 10 KW or less. In an embodiment, the pressure in the chamber 10 is controlled to be 5 m Torr or more and 30 m Torr or less.

### (Step STA3)

In step STA3, the bias signal is supplied to the constituent member CP. In an embodiment, the bias signal may be a bias RF signal. In an example, the bias RF signal is supplied from the second RF generator 31b to the lower electrode of the substrate support 11. The bias RF signal may have a frequency of 40 MHz or less. In an embodiment, the bias signal may be a bias DC signal. In an example, the bias DC signal is supplied from the DC generator 32a to the lower electrode of the substrate support 11. In an example, the bias DC signal is supplied from the DC generator 32b to the upper electrode of the shower head 13. The bias DC signal may be negatively polarized. In an embodiment, the pressure in the chamber 10 is controlled to be 5 m Torr or more and 30 m Torr or less.

The energy of the ions incident on the constituent member CP in step STA3 (the energy of the bias signal supplied to the constituent member CP) may be greater than the energy of the ions incident on the constituent member CP in step ST1 (the energy of the bias signal supplied to the constituent member CP) when forming the precoat PC. In an embodiment, the energy of the ions incident on the constituent member CP in step STA3 (the energy of the bias signal supplied to the constituent member CP) may be 120 eV or more. The energy of the ions incident on the constituent member CP may be adjusted by controlling at least one selected from the group consisting of the power (electric power or voltage) of the bias signal supplied to the constituent member CP, the frequency of the bias signal, the power of the source RF signal, the frequency of the source signal, and the pressure in the chamber 10. In addition, as in step ST1 described above, in a case where the first processing gas includes a gas other than the first gas, the energy of the ions incident on the first constituent member may be adjusted by controlling the type and/or the flow rate of the gas. In an example, in a case where the first processing gas further includes a noble gas, the energy of the ions incident on the constituent member CP may be adjusted to 90 eV or more by controlling the type and/or the flow rate of the noble gas.

By supplying the bias signal to the constituent member CP, ions in the plasma are driven into the first intermediate film IL1 formed on the surface of the constituent component CP. The energy of the ions incident on the constituent member CP may be greater than the energy of the ions incident on the constituent member CP when forming the precoat PC on the constituent member CP in step ST1. In this manner, the adhesive force at the interface between the first intermediate film IL1 and the constituent member CP may be increased. It is considered that a mixed layer containing carbon (C) and silicon (Si) is formed thickly between the carbon (C) in the first intermediate film IL1 and the material (for example, silicon) in the constituent member CP, and thus the chemical bond (for example, C—Si bond) between the two increases. The first intermediate film IL1 may function as an adhesion layer that suppresses the precoat PC from being peeled off from the constituent member CP in the plasma processing in step ST2.

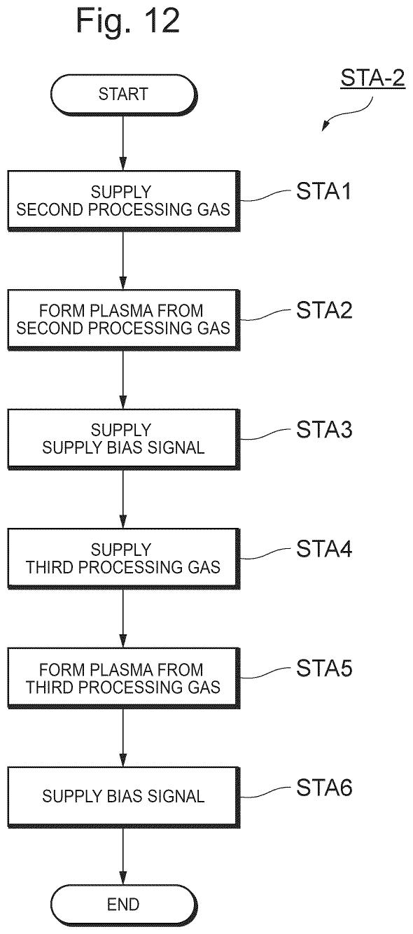

FIG. 12 is a flowchart illustrating a second example of step STA (hereinafter, also referred to as “step STA-2”). Step STA-2 is an example of a step of forming the first intermediate film IL1 and the second intermediate film IL2 illustrated in FIG. 10B. That is, in step STA-2, the first intermediate film IL1 and the second intermediate film IL2 are formed on the constituent member CP in the chamber 10.

As illustrated in FIG. 12, step STA-2 includes steps STA1 to STA3 as in the first example (step STA-1). In addition, step STA-2 includes step STA4 of supplying the third processing gas to the chamber 10, step STA5 of forming plasma from the third processing gas, and step STA6 of supplying the bias signal to the chamber 10, after step STA3 is executed.

In steps STA1 to STA3, the same description as the first example (step STA-1) will be omitted. In step STA4 to step STA6, the second intermediate film IL2 is formed on the first intermediate film IL1.

First, in step STA4, the third processing gas is supplied from the gas supply 20 into the plasma processing space 10s of the chamber 10. The third processing gas includes the above-described first gas. In an embodiment, the third processing gas may be the same as the second processing gas. In an embodiment, the third processing gas may have a different type or composition of gas from the second processing gas.

Step STA5 is executed in the same manner as step STA2. In step STA2, the second intermediate film IL2 is formed on the first intermediate film IL1. In an embodiment, the power of the source RF signal may be the same as or different from the power of the source RF signal in step STA2. In an embodiment, in a case where the third processing gas includes the above-mentioned addition gas (the first addition gas and/or the second addition gas), the pressure in the chamber 10 is controlled to be 5 m Torr or more and 30 m Torr or less. In an embodiment, in a case where the third processing gas does not include the above-described addition gas, the pressure in the chamber 10 is controlled to be 30 m Torr or more and 1000 m Torr or less.

Step STA6 is executed in the same manner as step STA3. However, in a case where the third processing gas does not include the above-described addition gas (the first addition gas and/or the second addition gas), the energy of the ions incident on the constituent member CP (the energy of the bias signal supplied to the constituent member CP) may be 90 eV or less. In a case where the third processing gas includes the above-mentioned addition gas (the first addition gas and/or the second addition gas), the energy of the ions incident on the constituent member CP (the energy of the bias signal supplied to the constituent member CP) may be 90 eV or more. As a result, the second intermediate film IL2 may be a soft film having a smaller film density than the precoat PC. In an embodiment, the second intermediate film IL2 may function as a stress relaxing layer that relaxes the stress applied to the constituent member CP from the precoat PC. As a result, even in a case where the film thickness of the precoat PC is large (for example, 400 nm or more), the precoat PC may be suppressed from being peeled off from the constituent member CP in the plasma processing in step ST2.

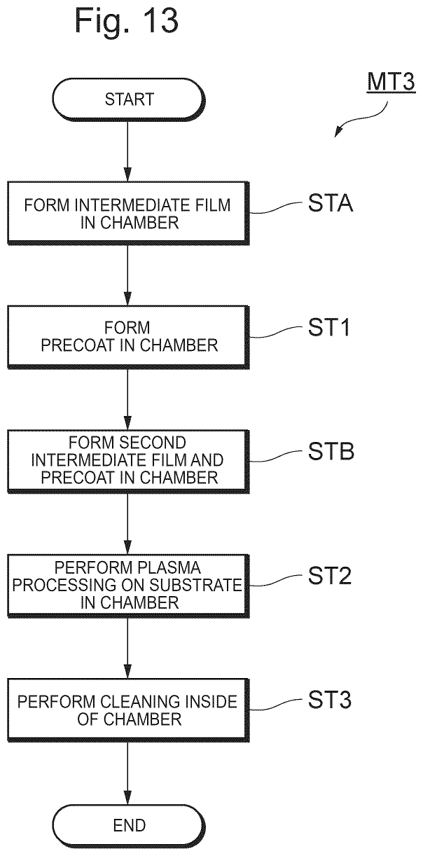

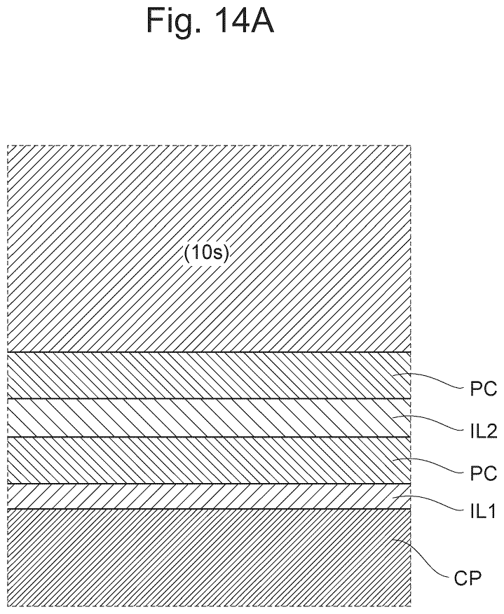

FIG. 13 is a flowchart illustrating another example (hereinafter, also referred to as a “method MT3”) of the present processing method. As illustrated in FIG. 13, the method MT3 includes step STA of forming the intermediate film in the chamber, step ST1 of forming the precoat in the chamber, step STB of forming the second intermediate film and the precoat in the chamber, and step ST2 of performing the plasma processing on the substrate. The method MT3 may further include step ST3 of performing cleaning inside of the chamber 10.

The method MT3 is different from the method MT2 in that step STB is provided between step ST1 and step ST2. Hereinafter, step STB will be described, and the other description will be omitted.

In step STB, one or a plurality of film stacks in which the second intermediate film IL2 and the precoat PC are stacked in this order on the precoat PC formed in step ST1 is formed. In an embodiment, the formation of the second intermediate film IL2 may be executed in the same manner as in step STA4 to step STA6 (FIG. 12). In an embodiment, the formation of the precoat PC may be executed in the same manner as in step ST11 to step ST13 (FIG. 4). Step STB may be continuously executed from step ST1 as in the transition from step STA to step ST1 described above. Similarly, in step STB, the formation of the second interlayer IL2 and the precoat PC may be continuously executed.

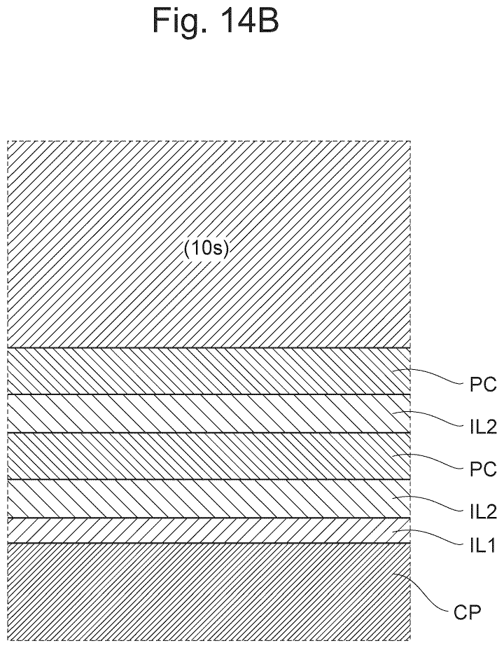

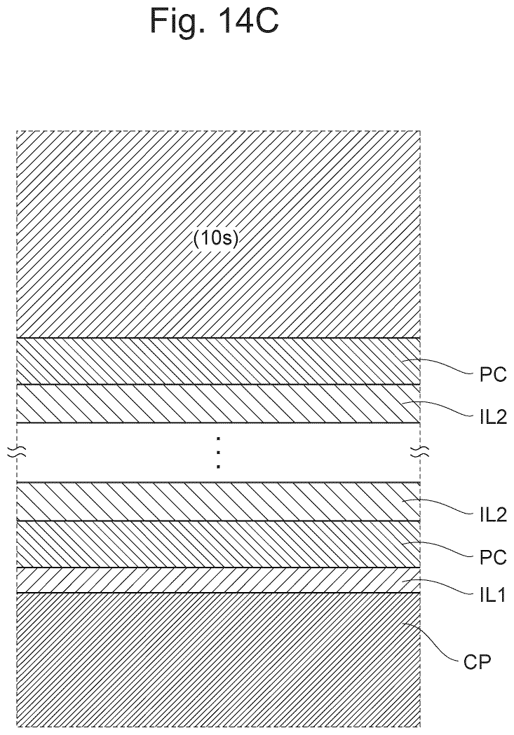

FIGS. 14A to 14C are diagrams illustrating examples of the cross-sectional structure of the constituent member CP at the end of step STA, step ST1, and step STB, respectively. In the example illustrated in FIG. 14A, a one layer of a film stack (step STB) consisting of the first intermediate film IL1 (step STA), the precoat PC (step ST1), the second intermediate film IL2, and the precoat PC is formed on the constituent member CP. In the example illustrated in FIG. 14A, the film thicknesses, the film densities, and the like of the two precoats PC may be the same as or different from each other.

In the example illustrated in FIG. 14B, a one layer of a film stack (step STB) consisting of the first intermediate film IL1, the second intermediate film IL2 (step STA), the precoat PC (step ST1), the second intermediate film IL2, and the precoat PC is formed on the constituent member CP. In the example illustrated in FIG. 14B, the film thicknesses, the film densities, and the like of the two precoats PC may be the same as or different from each other. In addition, the film thicknesses, the film densities, and the like of the two intermediate films IL2 may be the same or different from each other.

In the example illustrated in FIG. 14C, a plurality of film stacks (step STB) consisting of the first intermediate film IL1 (step STA), the precoat PC (step ST1), the second intermediate film IL2, and the precoat PC is formed on the constituent member CP. In the example illustrated in FIG. 14C, the film thicknesses, the film densities, and the like of the plurality of precoats PC may be the same as each other or may be different from each other, or at least one of them may be different. In addition, the film thicknesses, the film densities, and the like of the plurality of intermediate films IL2 may be the same or may be different from each other, or at least one of them may be different.

In the present processing method, the bias signal may be supplied to the constituent member (second constituent member) different from the constituent member (first constituent member) on which the precoat is formed. In an example, in a case where the precoat is formed on the side wall 10a, the shield 50, and/or the baffle plate 60, the bias signal may be supplied to the lower electrode of the substrate support 11 or the upper electrode of the shower head 13. In this case, at least one selected from the group consisting of the power (electric power or voltage) of the bias signal, the frequency of the bias signal, the power of the source RF signal, the frequency of the source RF signal, and the pressure in the chamber 10 may be controlled such that the energy of the ions incident on the first constituent member is 90 eV or more. In a case where the first processing gas includes a gas other than the first gas, the energy of the ions incident on the first constituent member may be adjusted by controlling the type and/or the flow rate of the gas. In an example, in a case where the first processing gas further includes a noble gas, the energy of the ions incident on the first constituent member may be adjusted to 90 eV or more by controlling the type and/or the flow rate of the noble gas.

In addition, in the present processing method, the bias signal may be supplied to other constituent members CP in addition to or instead of the lower electrode of the substrate support 11 or the upper electrode of the shower head 13. In an embodiment, in step ST1, step STA, and/or step STB, the bias signal may be supplied to the edge ring of the ring assembly 112, the side wall 10a, the shield 50, and/or the baffle plate 60. For example, a third DC generator connected to the side wall 10 may be provided in the DC power supply 32 of the power supply 30 of the plasma processing apparatus 1. Then, in step ST1, step STA, and/or step STB, the third DC signal generated by the third DC generator may be supplied to the side wall 10a as the bias signal.

According to one exemplary embodiment of the present disclosure, it is possible to provide a technique for controlling the film quality of the precoat.

The embodiments of the present disclosure further include the following aspects.

### (Addendum 1)

A plasma processing method, including:
(a) forming a precoat on a constituent member in a chamber, the precoat including a carbon-containing film;
(b) providing a first substrate on a substrate support in the chamber; and
(c) performing plasma processing on the first substrate, wherein the (a) includes
   (a1) supplying a first processing gas including a first gas in the chamber, the first gas containing carbon and hydrogen,
   (a2) supplying a source RF signal to form plasma from the first processing gas, and
   (a3) supplying a bias signal of 90 eV or more to the constituent member in the chamber.

### (Addendum 2)

The plasma processing method according to Addendum 1, in which, in the (a3), the bias signal is a bias DC signal or a bias RF signal of 40 MHz or less.

### (Addendum 3)

The plasma processing method according to any one of Addendum 1 or 2, in which the first gas is at least one of a hydrocarbon gas and a halogenated hydrocarbon gas.

### (Addendum 4)

The plasma processing method according to any one of Addenda 1 to 3, in which the first processing gas further includes at least one addition gas selected from the group consisting of a nitrogen-containing gas, a halogen-containing gas, and a boron-containing gas.

### (Addendum 5)

The plasma processing method according to Addendum 4, in which a flow rate ratio of the addition gas to the first gas is 50 vol % or less.

### (Addendum 6)

The plasma processing method according to any one of Addenda 1 to 5, in which the first processing gas further includes a noble gas.

### (Addendum 7)

The plasma processing method according to any one of Addenda 1 to 6, in which the (a) further includes, after the (a1) to the (a3), (a4) reforming the precoat with plasma formed from a processing gas including at least one gas selected from the group consisting of a nitrogen-containing gas, a halogen-containing gas, and a boron-containing gas.

### (Addendum 8)

The plasma processing method according to any one of Addenda 1 to 7, in which the (a) is executed while a second substrate different from the first substrate is disposed on the substrate support.

### (Addendum 9)

The plasma processing method according to Addendum 8, in which in the (a3), a bias signal of 120 eV or more is supplied to the constituent member in the chamber.

### (Addendum 10)

The plasma processing method according to any one of Addenda 1 to 7, in which the (a) is executed while a surface of the substrate support is exposed to a space in the chamber.

### (Addendum 11)

The plasma processing method according to Addendum 10, in which in the (a3), a bias signal of 90 eV or more and 120 eV or less is supplied to the substrate support in the chamber.

### (Addendum 12)

The plasma processing method according to any one of Addenda 1 to 11, in which the constituent member in the chamber is a portion exposed to plasma in the (c).

### (Addendum 13)

The plasma processing method according to any one of Addenda 1 to 12, in which the constituent member in the chamber includes at least one selected from the group consisting of the substrate support, an upper electrode disposed to face the substrate support, an inner wall of the chamber, and a baffle plate.

### (Addendum 14)

The plasma processing method according to any one of Addenda 1 to 13, further including:
(d) forming an intermediate film on a surface of the constituent member before the (a),
in which the (d) includes
   (d1) supplying a second processing gas including a second gas in the chamber, the second gas containing carbon and hydrogen,
   (d2) supplying a source RF signal to form plasma from the second processing gas, and
   (d3) supplying a bias signal having energy equal to or greater than the bias signal in the (a3) to the constituent member in the chamber.

### (Addendum 15)

The plasma processing method according to any one of Addenda 1 to 14, in which the second processing gas further includes at least one addition gas selected from the group consisting of a nitrogen-containing gas, a halogen-containing gas, and a boron-containing gas.

### (Addendum 16)

The plasma processing method according to Addendum 14 or 15, in which the (d) further includes, after the (d1) to the (d3),
(d4) supplying a third processing gas including a third gas in the chamber, the third gas containing carbon and hydrogen, and the third processing gas not including a nitrogen-containing gas, a halogen-containing gas, and a boron-containing gas,
(d5) supplying a source RF signal to form plasma from the third processing gas, and
(d6) supplying a bias signal of 90 eV or less to the constituent member in the chamber.

### (Addendum 17)

The plasma processing method according to any one of Addenda 14 to 16, in which between the (a) and the (b),
a set is repeated once or a plurality of times, the set including
   (e1) supplying a third processing gas including a third gas in the chamber, the third gas containing carbon and hydrogen, and the third processing gas not including a nitrogen-containing gas, a halogen-containing gas, and a boron-containing gas,
   (e2) supplying a source RF signal to form plasma from the third processing gas,
   (e3) supplying a bias signal of 90 eV or less to the constituent member in the chamber,
   (e4) supplying the first processing gas in the chamber,
   (e5) supplying a source RF signal to form plasma from the first processing gas, and
   (e6) supplying a bias signal of 90 eV or more to the constituent member in the chamber.

### (Addendum 18)

The plasma processing method according to Addendum 14 or 15, in which the (d) further includes, after the (d1) to the (d3),
(d7) supplying a fourth processing gas in the chamber, the fourth processing gas including a fourth gas and an addition gas, the fourth gas containing carbon and hydrogen, and the addition gas being at least one selected from the group consisting of a nitrogen-containing gas, a halogen-containing gas, and a boron-containing gas,
(d8) supplying a source RF signal to form plasma from the fourth processing gas, and
(d9) supplying a bias signal of 120 eV or more to the constituent member in the chamber.

### (Addendum 19)

The plasma processing method according to any one of Addenda 14, 15, and 18, in which between the (a) and the (b),
a set is repeated once or a plurality of times, the set including
   (e7) supplying a fourth processing gas in the chamber, the fourth processing gas including a fourth gas and an addition gas, the fourth gas containing carbon and hydrogen, and the addition gas being at least one selected from the group consisting of a nitrogen-containing gas, a halogen-containing gas, and a boron-containing gas,
   (e8) supplying a source RF signal to form plasma from the fourth processing gas,
   (e9) supplying a bias signal of 120 eV or more to the constituent member in the chamber,
   (e10) supplying the first processing gas in the chamber,
   (e11) supplying a source RF signal to form plasma from the first processing gas, and
   (e12) supplying a bias signal of 90 eV or more to the constituent member in the chamber.

### (Addendum 20)

A plasma processing method, including:
(a) forming a precoat on a first constituent member in a chamber, the precoat including a carbon-containing film;
(b) providing a first substrate on a substrate support in the chamber; and
(c) performing plasma processing on the first substrate, in which
the (a) includes
   (a1) supplying a first processing gas including a first gas in the chamber, the first gas containing carbon and hydrogen,
   (a2) supplying a source RF signal to form plasma from the first processing gas, and
   (a3) supplying a bias signal to the first constituent member in the chamber and/or a second constituent member in the chamber, the second constituent member being different from the first constituent member, and
   controlling at least one selected from the group consisting of a power of the bias signal, a frequency of the bias signal, a power of the source signal, a frequency of the source signal, and a pressure of the chamber such that an energy of ions incident on the first constituent member is 90 eV or more.

### (Addendum 21)

The plasma processing method according to Addendum 20, in which the first processing gas further includes a noble gas, and
the (a) further includes controlling a type and/or a flow rate of the noble gas such that the energy of the ions incident on the first constituent member is 90 eV or more.

### (Addendum 22)

A plasma processing method, including:
(a) forming an intermediate film on a first constituent member in a chamber;
(b) forming a precoat including a carbon-containing film on the intermediate film;
(c) providing a first substrate on a substrate support in the chamber; and
(d) performing plasma processing on the first substrate, in which
the (b) includes
   (b1) supplying a first processing gas including a first gas in the chamber, the first gas containing carbon and hydrogen,
   (b2) supplying a source RF signal to form plasma from the first processing gas, and
   (b3) supplying a first bias signal to the first constituent member in the chamber and/or a second constituent member in the chamber, the second constituent member being different from the first constituent member, and
the (a) includes
   (a1) supplying a second processing gas including a second gas in the chamber, the second gas containing carbon and hydrogen,
   (a2) supplying a source RF signal to form plasma from the second processing gas, and
   (a3) supplying a second bias signal equal to or greater than the first bias signal to the first constituent member and/or the second constituent member in the chamber.

### (Addendum 23)

The plasma processing method according to Addendum 22, in which
the intermediate film includes a first intermediate film and a second intermediate film on the first intermediate film, and
a thickness of the second intermediate film is equal to or greater than a thickness of the first intermediate film.

### (Addendum 24)

A precoat forming method, including:
(a1) supplying a first processing gas including a first gas in the chamber, the first gas containing carbon and hydrogen;
(a2) supplying a source RF signal to form plasma from the first processing gas; and
(a3) supplying a bias signal of 90 eV or more to a constituent member in the chamber, and forming a precoat including a carbon-containing film on the constituent member.

### (Addendum 25)

A plasma processing apparatus, including:
a chamber;
a substrate support in the chamber; and
a controller,
wherein the controller is configured to execute
   (a) forming a precoat including a carbon-containing film on a constituent member in the chamber,
   (b) providing a first substrate on the substrate support in the chamber, and
   (c) performing plasma processing on the first substrate, and
the (a) includes
   (a1) supplying a first processing gas including a first gas in the chamber, the first gas containing carbon and hydrogen,
   (a2) supplying a source RF signal to form plasma from the first processing gas, and
   (a3) supplying a bias signal of 90 eV or more to the constituent member in the chamber.

### (Addendum 26)

A device processing method, including:
(a) forming a precoat on a constituent member in a chamber, the precoat including a carbon-containing film;
(b) providing a first substrate on a substrate support in the chamber; and
(c) performing plasma processing on the first substrate,
wherein the (a) includes
   (a1) supplying a first processing gas including a first gas in the chamber, the first gas containing carbon and hydrogen,
   (a2) supplying a source RF signal to form plasma from the first processing gas, and
   (a3) supplying a bias signal of 90 eV or more to the constituent member in the chamber.

### (Addendum 27)

A program causing a computer of a plasma processing apparatus, the plasma processing apparatus including a chamber and a controller, the controller being configured to cause:
(a) forming a precoat on a constituent member in the chamber, the precoat including a carbon-containing film;
(b) providing a first substrate on the substrate support in the chamber; and
(c) performing plasma processing on the first substrate,
wherein the (a) executes
   (a1) supplying a first processing gas including a first gas in the chamber, the first gas containing carbon and hydrogen,
   (a2) supplying a source RF signal to form plasma from the first processing gas, and
   (a3) supplying a bias signal of 90 eV or more to the constituent member in the chamber.

### (Addendum 28)

A storage medium in which the program according to Addendum 27 is stored.

Each of the above embodiments is described for the purpose of description, and it is not intended to limit the scope of the present disclosure. Each of the above embodiments may be modified in various ways without departing from the scope and gist of the present disclosure. For example, some constitutional elements in one embodiment are able to be added to other embodiments. In addition, some configuration elements in one embodiment are able to be replaced with corresponding configuration elements in another embodiment.

What is claimed is:

1. A plasma processing method, including:
(a) forming a precoat on a constituent member in a chamber, the precoat including a carbon-containing film;
(b) providing a first substrate on a substrate support in the chamber; and
(c) performing plasma processing on the first substrate,
wherein the (a) includes:
(a1) supplying a first processing gas including a first gas in the chamber, the first gas containing carbon and hydrogen,
(a2) supplying a source RF signal to form plasma from the first processing gas, and
(a3) supplying a bias signal of 90 eV or more to the constituent member in the chamber.

2. The plasma processing method according to claim 1, wherein, in the (a3), the bias signal is a bias DC signal or a bias RF signal of 40 MHz or less.

3. The plasma processing method according to claim 1, wherein the first gas is at least one of a hydrocarbon gas and a halogenated hydrocarbon gas.

4. The plasma processing method according to claim 1, wherein the first processing gas further includes at least one addition gas selected from the group consisting of a nitrogen-containing gas, a halogen-containing gas, and a boron-containing gas.

5. The plasma processing method according to claim 4, wherein a flow rate ratio of the addition gas to the first gas is 50 vol % or less.

6. The plasma processing method according to claim 1, wherein the first processing gas further includes a noble gas.

7. The plasma processing method according to claim 1, wherein the (a) further includes, after the (a1) to the (a3),
(a4) reforming the precoat with plasma formed from a processing gas including at least one gas selected from the group consisting of a nitrogen-containing gas, a halogen-containing gas, and a boron-containing gas.

8. The plasma processing method according to claim 1, wherein the (a) is executed while a second substrate different from the first substrate is disposed on the substrate support.

9. The plasma processing method according to claim 8, wherein in the (a3), a bias signal of 120 eV or more is supplied to the constituent member in the chamber.

10. The plasma processing method according to claim 1, wherein the (a) is executed while a surface of the substrate support is exposed to a space in the chamber.

11. The plasma processing method according to claim 10, wherein in the (a3), a bias signal of 90 eV or more and 120 eV or less is supplied to the substrate support in the chamber.

12. The plasma processing method according to claim 1, wherein the constituent member in the chamber includes at least one selected from the group consisting of the substrate support, an upper electrode disposed to face the substrate support, an inner wall of the chamber, and a baffle plate.

13. The plasma processing method according to claim 1, further comprising:
(d) forming an intermediate film on a surface of the constituent member before the (a),
wherein the (d) includes
(d1) supplying a second processing gas including a second gas in the chamber, the second gas containing carbon and hydrogen,
(d2) supplying a source RF signal to form plasma from the second processing gas, and
(d3) supplying a bias signal having energy equal to or greater than the bias signal in the (a3) to the constituent member in the chamber.

14. The plasma processing method according to claim 13, wherein the second processing gas further includes at least one addition gas selected from the group consisting of a nitrogen-containing gas, a halogen-containing gas, and a boron-containing gas.

15. The plasma processing method according to claim 13, wherein the (d) further includes, after the (d1) to the (d3),
(d4) supplying a third processing gas including a third gas in the chamber, the third gas containing carbon and hydrogen, and the third processing gas not including a nitrogen-containing gas, a halogen-containing gas, and a boron-containing gas,
(d5) supplying a source RF signal to form plasma from the third processing gas, and
(d6) supplying a bias signal of 90 eV or less to the constituent member in the chamber.

16. The plasma processing method according to claim 13, wherein between the (a) and the (b),
a set is repeated once or a plurality of times, the set including:
(e1) supplying a third processing gas including a third gas in the chamber, the third gas containing carbon and hydrogen, and the third processing gas not including a nitrogen-containing gas, a halogen-containing gas, and a boron-containing gas,
(e2) supplying a source RF signal to form plasma from the third processing gas,
(e3) supplying a bias signal of 90 eV or less to the constituent member in the chamber,
(e4) supplying the first processing gas in the chamber,
(e5) supplying a source RF signal to form plasma from the first processing gas, and
(e6) supplying a bias signal of 90 eV or more to the constituent member in the chamber.

17. The plasma processing method according to claim 13, wherein the (d) further includes, after the (d1) to the (d3),
(d7) supplying a fourth processing gas in the chamber, the fourth processing gas including a fourth gas and an addition gas, the fourth gas containing carbon and hydrogen, and the addition gas being at least one selected from the group consisting of a nitrogen-containing gas, a halogen-containing gas, and a boron-containing gas,
(d8) supplying a source RF signal to form plasma from the fourth processing gas, and
(d9) supplying a bias signal of 120 eV or more to the constituent member in the chamber.

18. The plasma processing method according to claim 13, wherein between the (a) and the (b),
a set is repeated once or a plurality of times, the set including:
(e7) supplying a fourth processing gas in the chamber, the fourth processing gas including a fourth gas and an addition gas, the fourth gas containing carbon and hydrogen, and the addition gas being at least one selected from the group consisting of a nitrogen-containing gas, a halogen-containing gas, and a boron-containing gas,
(e8) supplying a source RF signal to form plasma from the fourth processing gas,
(e9) supplying a bias signal of 120 eV or more to the constituent member in the chamber,
(e10) supplying the first processing gas in the chamber,
(e11) supplying a source RF signal to form plasma from the first processing gas, and
(e12) supplying a bias signal of 90 eV or more to the constituent member in the chamber.

19. A plasma processing method, comprising:
(a) forming a precoat on a first constituent member in a chamber, the precoat including a carbon-containing film;
(b) providing a first substrate on a substrate support in the chamber; and
(c) performing plasma processing on the first substrate,
wherein the (a) includes
(a1) supplying a first processing gas including a first gas in the chamber, the first gas containing carbon and hydrogen,
(a2) supplying a source RF signal to form plasma from the first processing gas,
(a3) supplying a bias signal to the first constituent member in the chamber and/or a second constituent member in the chamber, the second constituent member being different from the first constituent member, and
controlling at least one selected from the group consisting of a power of the bias signal, a frequency of the bias signal, a power of the source signal, a frequency of the source signal, and a pressure of the chamber such that an energy of ions incident on the first constituent member is 90 eV or more.

20. A plasma processing apparatus, comprising:
a chamber;
a substrate support in the chamber; and
control circuitry configured to execute:
(a) forming a precoat including a carbon-containing film on a constituent member in the chamber,
(b) providing a first substrate on the substrate support in the chamber, and
(c) performing plasma processing on the first substrate, and
the (a) includes
(a1) supplying a first processing gas including a first gas in the chamber, the first gas containing carbon and hydrogen,
(a2) supplying a source RF signal to form plasma from the first processing gas, and
(a3) supplying a bias signal of 90 eV or more to the constituent member in the chamber.
